(19) United States
(12) Patent Application Publication
(10) Pub. No.: US 2022/0173709 A1
(43) Pub. Date: Jun. 2, 2022

(54) PIEZOELECTRIC VIBRATOR

(71) Applicant: Murata Manufacturing Co., Ltd., Nagaokakyo-shi (JP)

(72) Inventors: Toru KIZU, Nagaokakyo-shi (JP); Hiroshi IBARAGI, Nagaokakyo-shi (JP); Sachihito NAKAFUKU, Nagaokakyo-shi (JP); Yasuhiro HORITA, Nagaokakyo-shi (JP)

(21) Appl. No.: 17/672,317

(22) Filed: Feb. 15, 2022

Related U.S. Application Data
(63) Continuation of application No. PCT/JP2020/018793, filed on May 11, 2020.

(30) Foreign Application Priority Data
Sep. 25, 2019 (JP) 2019-173741

(51) Int. Cl. H03H 3/02; H03H 9/10; H01L 23/10

(52) U.S. Cl. CPC H03H 3/02; H01L 23/10; H03H 9/1014

(57) ABSTRACT

A crystal vibrator is provided that includes a base having a main surface, a piezoelectric vibration element mounted on the main surface of the base, a cover that has a recess in which the piezoelectric vibration element is accommodated and that is tougher than the base, and a bonding member that is provided in a frame-like shape so as to surround the piezoelectric vibration element when the main surface of the base is seen in plan view and that bonds the base to the cover. When the main surface of the base is seen in plan view, at least part of an outer edge part of the cover member is located outside the base.

### CROSS REFERENCE TO RELATED APPLICATIONS

The present application is a continuation of PCT/JP2020/018793 filed May 11, 2020, which claims priority to Japanese Patent Application No. 2019-173741, filed Sep. 25, 2019, the entire contents of each of which are incorporated herein by reference.

### TECHNICAL FIELD

The present invention relates to a piezoelectric vibrator.

### BACKGROUND

Vibrators are currently used as timing devices, sensors, oscillators, and so on in various electronic appliances, such as mobile communication terminals, communication base stations, home appliances, and so forth. As the functionality of electronic devices increases, there is a demand for smaller and thinner piezoelectric vibrators.

Japanese Patent No. 5790878 (hereinafter “Patent Document 1”) discloses a crystal vibrator that includes a base member having a flat-plate-shaped base composed of a ceramic, a crystal vibration element mounted on the base member, a cover member composed of a metal and having a recess that opens toward the base member, and a bonding member composed of a metal that bonds the base member and the cover member to each other. The crystal vibration element is disposed inside a reduced pressure sealed space.

In the crystal vibrator disclosed in Patent Document 1, when the strength of the base has been reduced as a result of the base having been reduced in size and thickness, collisions between the bases during leak screening, a cleaning step, and so forth may result in the bases being damaged and the yield of crystal vibrators being decreased.

### SUMMARY OF THE INVENTION

Accordingly, it is an object of the present invention to provide a piezoelectric vibrator that enables a decrease in yield to be reduced.

In an exemplary aspect, a crystal vibrator is provided that includes a base having a main surface, a piezoelectric vibration element mounted on the main surface of the base, a cover that has a recess in which the piezoelectric vibration element is accommodated and that is tougher than the base, and a bonding member that is provided in a frame-like shape so as to surround the piezoelectric vibration element when the main surface of the base is seen in plan view and that bonds the base to the cover. Moreover, when the main surface of the base is seen in plan view, at least part of an outer edge part of the cover member is located outside the base.

According to the exemplary embodiment of the present invention, a piezoelectric vibrator is provided that enables a decrease in yield to be reduced.

### BRIEF DESCRIPTION OF DRAWINGS

FIG. 1 is an exploded perspective view schematically illustrating the configuration of a crystal vibrator according to a first exemplary embodiment.

FIG. 2 is a sectional view schematically illustrating the configuration of the crystal vibrator according to the first exemplary embodiment.

FIG. 3 is a plan view schematically illustrating the positional relationship between a base member, a bonding member, and a cover member in the first exemplary embodiment.

FIG. 4 is a flowchart schematically illustrating a method of manufacturing the crystal vibrator according to the first exemplary embodiment.

FIG. 5 is a sectional view schematically illustrating a step of preparing a parent substrate.

FIG. 6 is a sectional view schematically illustrating a step of forming grooves in the parent substrate.

FIG. 7 is a sectional view schematically illustrating a step of dividing the parent substrate.

FIG. 8 is a sectional view schematically illustrating a step of bonding a base member and a cover member to each other.

FIG. 9 is a sectional view schematically illustrating a step of removing a crystal vibrator.

FIG. 10 is a plan view schematically illustrating the positional relationship between a base member, a bonding member, and a cover member in a second exemplary embodiment.

FIG. 11 is a plan view schematically illustrating the positional relationship between a base member, a bonding member, and a cover member in a third exemplary embodiment.

FIG. 12 is a sectional view schematically illustrating the configuration of a crystal vibrator according to a fourth exemplary embodiment.

### DETAILED DESCRIPTION OF EMBODIMENTS

Hereafter, exemplary embodiments of the present invention will be described while referring to the drawings. The drawings for each embodiment are representative, the dimensions and shapes of the individual parts are schematically illustrated, and the technical scope of the invention of the present application should not be interpreted as being limited to that of the embodiments.

### First Exemplary Embodiment

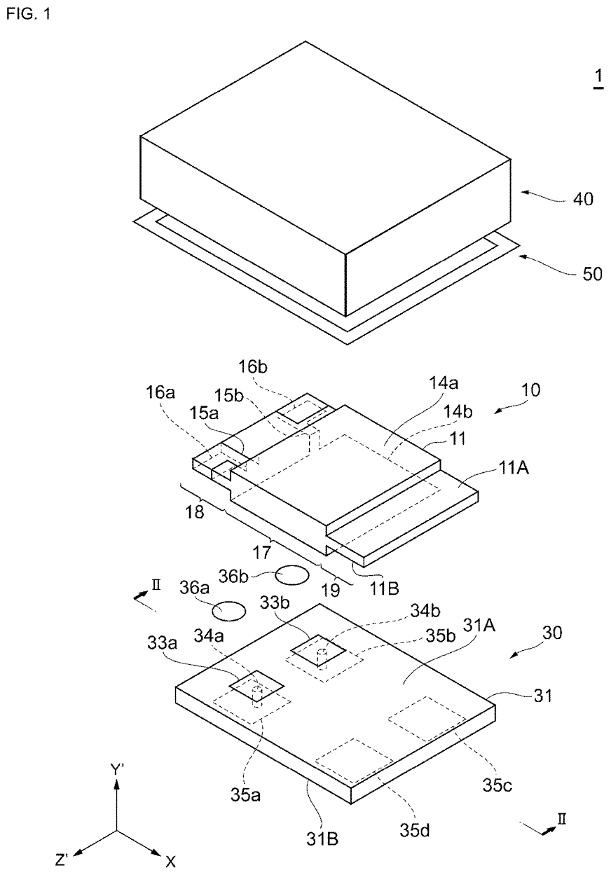

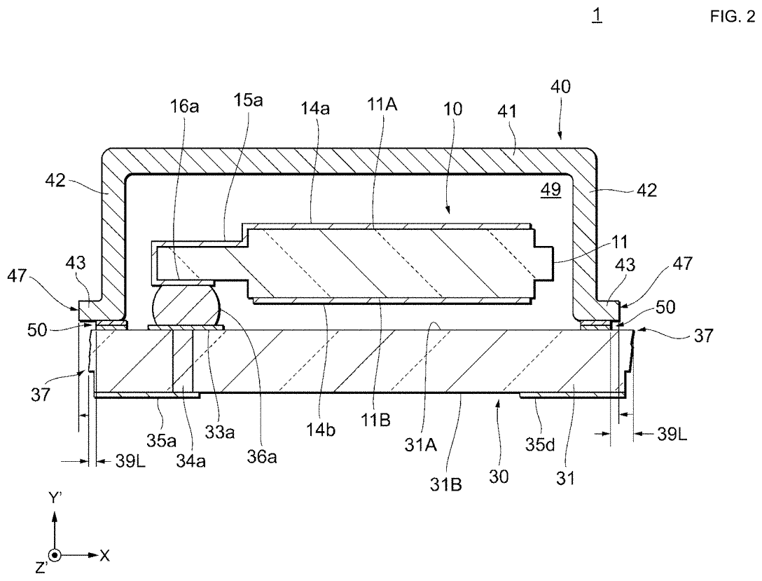

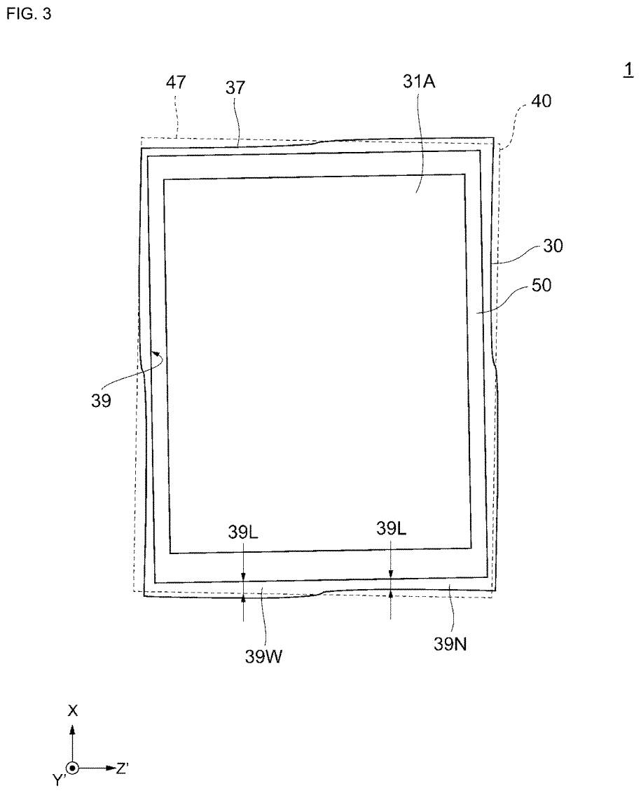

The configuration of a crystal vibrator 1 according to a first exemplary embodiment will be described while referring to FIGS. 1 to 3. FIG. 1 is an exploded perspective view schematically illustrating the configuration of the crystal vibrator according to the first embodiment. FIG. 2 is a sectional view schematically illustrating the configuration of the crystal vibrator according to the first embodiment. FIG. 3 is a plan view schematically illustrating the positional relationship between a base member, a bonding member, and a cover member in the first embodiment.

For convenience, each drawing is labeled with a Cartesian coordinate system consisting of an X axis, a Y′ axis, and a Z′ axis in order to help clarify the relationships between the individual drawings and to aid in understanding the positional relationships between the individual components. It is noted that the X axis, the Y′ axis, and the Z′ axis correspond to one another in the individual drawings. Moreover, the X axis, the Y′ axis, and the Z′ axis respectively correspond to the crystallographic axes of a crystal piece 11, which is described later. For purposes of this disclosure, the X axis corresponds to an electrical axis (polarity axis), a Y axis corresponds to a mechanical axis, and a Z axis corresponds to an optical axis. The Y′ axis and the Z′ axis are axes obtained by respectively rotating the Y axis and the Z axis around the X axis in a direction from the Y axis towards the Z axis by 35 degrees 15 minutes±1 minute 30 seconds.

In the following description, a direction parallel to the X axis is referred to as an “X axis direction”, a direction parallel to the Y′ axis is referred to as a “Y′ axis direction”, and a direction parallel to the Z′ axis is referred to as a “Z′ axis direction”. In addition, the directions of the tips of the arrows of the X axis, Y′ axis, and Z′ axis are referred to as “+(plus)” directions and the directions opposite to these directions are referred to as “− (minus)” directions. For convenience, the +Y′ axis direction is described as being an upward direction and the −Y′ axis direction is described as being a downward direction, but the vertical orientation of the crystal vibrator 1 is not restricted. For example, in the following description, a +Y′ axis direction side and a −Y′ axis direction side of a crystal vibration element 10 are respectively referred to as an upper surface 11A and a lower surface 11B, but the crystal piece 11 may be disposed so that the upper surface 11A is located vertically below the lower surface 11B.

As shown, the crystal vibrator 1 includes the crystal vibration element 10, a base member 30 (or base), a cover member 40 (or cover), and a bonding member 50. Moreover, the crystal vibration element 10 is provided between the base member 30 and the cover member 40. The base member 30 and the cover member 40 form a holder or housing that accommodates the crystal vibration element 10. In the example illustrated in FIGS. 1 and 2, the base member 30 is shaped like a flat plate and the cover member 40 has a bottomed cavity, which is for accommodating the crystal vibration element 10, on the side thereof near the base member 30. The crystal vibration element 10 is mounted on the base member 30. It is noted that the shapes of the base member 30 and the cover member 40 are not limited to the above-described shapes so long as at least the part of the crystal vibration element 10 that is to be excited is accommodated in the holder. In addition, the method of holding the crystal vibration element 10 is not limited to the above-described method. For example, the base member 30 can have a bottomed cavity for accommodating the crystal vibration element 10 on the side thereof near the cover member 40. In addition, the base member 30 and the cover member 40 can sandwich therebetween the periphery of the part of the crystal vibration element 10 that is to be excited.

First, the crystal vibration element 10 will be described.

In particular, the crystal vibration element 10 is an element in which a crystal is constructed to vibrate using the piezoelectric effect and that performs conversion between electrical energy and mechanical energy. The crystal vibration element 10 includes the flake-like crystal piece 11, a first excitation electrode 14a and a second excitation electrode 14b that form a pair of excitation electrodes, a first lead-out electrode 15a and a second lead-out electrode 15b that form a pair of lead-out electrodes, and a first connection electrode 16a and a second connection electrode 16b that form a pair of connection electrodes.

The crystal piece 11 is, for example, an AT-cut crystal piece. The AT-cut crystal piece 11 is formed so that, in the Cartesian coordinate system consisting of the intersecting X axis, Y′ axis, and Z′ axis, a surface parallel to a plane defined by the X axis and the Z′ axis (hereafter, referred to as an “XZ′ plane” and applies in a similar manner for planes defined by other axes) is a main surface and a direction parallel to the Y′ axis is a thickness direction. For example, the AT-cut crystal piece 11 is formed by etching a crystal substrate (for example, a crystal wafer) obtained by cutting and grinding down a synthetic quartz crystal.

The crystal vibration element 10 employing the AT-cut crystal piece 11 has high frequency stability over a wide range of temperatures. In the AT-cut crystal vibration element 10, a thickness shear vibration mode is used as a main vibration. The angle of rotation of the Y′ axis and the Z′ axis in the AT-cut crystal piece 11 may be set so that the axes are tilted from 35 degrees 15 minutes to be equal to or more than −5 degrees and equal to or less than 15 degrees. It is noted that a cut other than an AT cut may be used for the cut angle of the crystal piece 11. For example, a BT cut, a GT cut, a SC cut, and so on may be used. Furthermore, the crystal vibration element can be a tuning-fork-type crystal vibration element employing a crystal piece having a cut angle called a Z-plate.

As further shown, the AT-cut crystal piece 11 has a long side direction in which long sides thereof that are parallel to the X axis direction extend, a short side direction in which short sides thereof that are parallel to the Z′ axis direction extend, and a thickness direction in which a thickness dimension thereof that is parallel to the Y′ axis direction extends. Moreover, the crystal piece 11 has an upper surface 11A located on the side near the cover member 40 and a lower surface 11B located on the side near the base member 30. The upper surface 11A and the lower surface 11B correspond to a pair of main surfaces of the crystal piece 11 that face each other. When the upper surface 11A of the crystal piece 11 is seen in plan view, the crystal piece 11 has a rectangular planar shape, and the crystal piece 11 includes an excitation part 17 that is located in the center and contributes to excitation and peripheral parts 18 and 19 that are adjacent to the excitation part 17. The excitation part 17 and the peripheral parts 18 and 19 are each formed in a strip shape across the entire width of the crystal piece 11 along the Z′ axis direction. The peripheral part 18 is located on the −X axis direction side of the excitation part 17 and the peripheral part 19 is located on the +X axis direction side of the excitation part 17.

It is noted that the crystal piece 11 is not limited to having a rectangular planar shape. In alternative aspects, the planar shape of the crystal piece 11 may instead be a polygonal shape, a circular shape, an elliptical shape, or a combination of these shapes. The planar shape of the crystal piece 11 may be a tuning fork shape. In other words, the crystal piece 11 may include a base part and vibration arm parts that extend in parallel from the base part. Moreover, a slit may be formed in the crystal piece 11 with the aim of suppressing leakage of vibrations and propagation of stress. The shapes of the excitation part 17 and the peripheral parts 18 and 19 of the crystal piece 11 are also not limited to strip-like shapes that extend across the entire width. For example, the planar shape of the excitation part may be an island-like shape that is adjacent to a peripheral part in the Z′ axis direction and the planar shape of the peripheral part may be formed in a frame-like shape that surrounds the excitation part.

As also shown, the crystal piece 11 has a so-called mesa structure in which the thickness of the excitation part 17 is larger than the thickness of the peripheral parts 18 and 19 (i.e., in the Y′ axis direction). In the crystal piece 11 having a mesa structure, leakage of vibrations from the excitation part 17 can be suppressed. The crystal piece 11 has a double-sided mesa structure and the excitation part 17 protrudes beyond the peripheral parts 18 and 19 on both the upper surface 11A side and the lower surface 11B side. The boundary between the excitation part 17 and the peripheral part 18 and the boundary between the excitation part 17 and the peripheral part 19 have tapered shapes in which the thickness changes in a continuous manner, but may instead have stepped shapes in which the thickness changes in a non-continuous manner. Moreover, the boundaries may have a convex shape in which the change in thickness varies in a continuous manner or may have a bevel shape in which the change in thickness varies in a non-continuous manner. The crystal piece 11 may have a one-sided mesa structure in which the excitation part 17 protrudes beyond the peripheral parts 18 and 19 on only the upper surface 11A side or the lower surface 11B side. In addition, the crystal piece 11 may have a so-called reverse mesa structure in which the thickness of the excitation part 17 is smaller than the thickness of the peripheral parts 18 and 19.

According to the exemplary aspect, the first excitation electrode 14a and the second excitation electrode 14b are provided on the excitation part 17 on opposing surfaces thereof. That is, the first excitation electrode 14a is provided on the upper surface 11A side of the crystal piece 11 and the second excitation electrode 14b is provided on the lower surface 11B side of the crystal piece 11. In other words, the first excitation electrode 14a is provided on the main surface of the crystal piece 11 that is located on the side near the cover member 40 and the second excitation electrode 14b is provided on the main surface of the crystal piece 11 that is located on the side near the base member 30. Accordingly, the first excitation electrode 14a and the second excitation electrode 14b face each other with the crystal piece 11 interposed therebetween. When the upper surface 11A of the crystal piece 11 is seen in plan view, the first excitation electrode 14a and the second excitation electrode 14b have rectangular shapes and are disposed so as to substantially entirely overlap each other. The first excitation electrode 14a and the second excitation electrode 14b are formed in strip-like shapes across the entire width of the crystal piece 11 along the Z′ axis direction. The first excitation electrode 14a and the second excitation electrode 14b correspond to a pair of electrodes, which each include individual electrodes, that face each other with the crystal piece 11 interposed therebetween.

It is noted that the planar shapes of the first excitation electrode 14a and the second excitation electrode 14b when the upper surface 11A of the crystal piece 11 is seen in plan view are not limited to rectangular shapes. Instead, the planar shapes of the first excitation electrode 14a and the second excitation electrode 14b may instead be polygonal shapes, circular shapes, elliptical shapes, or a combination of these shapes in alternative aspects.

As further shown, the first lead-out electrode 15a and the second lead-out electrode 15b are provided on the peripheral part 18. The first lead-out electrode 15a is provided on the upper surface 11A side of the crystal piece 11 and the second lead-out electrode 15b is provided on the lower surface 11B side of the crystal piece 11. The first lead-out electrode 15a electrically connects the first excitation electrode 14a and the first connection electrode 16a to each other. The second lead-out electrode 15b electrically connects the second excitation electrode 14b and the second connection electrode 16b to each other. For example, as illustrated in FIG. 1, one end of the first lead-out electrode 15a is connected to the first excitation electrode 14a on the excitation part 17 and the other end of the first lead-out electrode 15a is connected to the first connection electrode 16a on the peripheral part 18. In addition, one end of the second lead-out electrode 15b is connected to the second excitation electrode 14b on the excitation part 17 and the other end of the second lead-out electrode 15b is connected to the second connection electrode 16b on the peripheral part 18. The first lead-out electrode 15a and the second lead-out electrode 15b are preferably separated from each other when the upper surface 11A of the crystal piece 11 is seen in plan view in order to reduce stray capacitances. For example, the first lead-out electrode 15a is provided on the +Z′ axis direction side when looking from the second lead-out electrode 15b.

According to the exemplary aspect, the first connection electrode 16a and the second connection electrode 16b are electrodes for respectively connecting the first excitation electrode 14a and the second excitation electrode 14b to the base member 30, and are provided on the lower surface 11B side of the crystal piece 11 in the peripheral part 18. The first connection electrode 16a is provided at a corner formed between an edge of the crystal piece 11 on the −X axis direction side and an edge of the crystal piece 11 on the +Z′ axis direction side and the second connection electrode 16b is provided at a corner formed between an edge of the crystal piece 11 on the −X axis direction side and an edge of the crystal piece 11 on the −Z′ axis direction side.

One electrode group that includes the first excitation electrode 14a, the first lead-out electrode 15a, and the first connection electrode 16a is formed so that the electrodes are continuous with each other and is, for example, formed so that the electrodes are integrated with each other. The other electrode group that includes the second excitation electrode 14b, the second lead-out electrode 15b, and the second connection electrode 16b is formed so that the electrodes are continuous with each other and is, for example, formed so that the electrodes are integrated with each other. In this way, a pair of electrode groups are provided on the crystal vibration element 10. The pair of electrode groups of the crystal vibration element 10 has, for example, a multilayer structure in which a base layer and a surface layer are stacked in this order. The base layer is a layer that contacts the crystal piece 11 and is formed of a material having good adhesion to the crystal piece 11. The surface layer is a layer located at the outermost surface of each of the pair of electrode groups and is formed of a material having good chemical stability. With this configuration, peeling off and oxidation of the pair of electrode groups can be suppressed and a highly reliable crystal vibration element 10 can be provided. Moreover, in the exemplary aspect, the base layer contains chromium (Cr), for example, and the surface layer contains gold (Au), for example.

It is noted that the materials forming the pair of electrode groups of the crystal vibration element 10 are not limited to Cr and Au, and metal materials such as Ti, Mo, Al, Ni, Pd, Ag, and Cu may be included. The pair of electrode groups may contain an electrically conductive ceramic, an electrically conductive resin, and so on.

Next, the base member 30 (or base) will be described.

In particular, the base member 30 is constructed to hold the crystal vibrating element 10 in such a manner that the crystal vibration element 10 can be excited. The base member 30 includes a base 31 having an upper surface 31A and a lower surface 31B, which face each other. The upper surface 31A and the lower surface 31B correspond to a pair of main surfaces of the base 31 for purposes of this disclosure. The upper surface 31A is located on the side near the crystal vibration element 10 and the cover member 40 and corresponds to a mounting surface on which the crystal vibration element 10 is mounted. The lower surface 31B corresponds to a mounting surface that will face a circuit board when the crystal vibrator 1 is mounted on an external circuit board, for example. The base 31 includes of a sintered material such as insulating ceramic (e.g., alumina). The base 31 is preferably formed of a heat-resistant material from the viewpoint of suppressing generation of thermal stress. From the viewpoint of suppressing stress acting on the crystal vibration element 10 due to thermal history, the base 31 may be formed of a material having a coefficient of thermal expansion close to that of the crystal piece 11 and, for example, may be formed of a crystal.

As further shown, the base member 30 includes a first electrode pad 33a and a second electrode pad 33b, which form a pair of electrode pads. The first electrode pad 33a and the second electrode pad 33b are provided on the upper surface 31A of the base 31. In the exemplary aspect, the first electrode pad 33a and the second electrode pad 33b are terminals for electrically connecting the crystal vibration element 10 to the base member 30. From the viewpoint of suppressing degradation of reliability due to oxidation, the outermost surfaces of the first electrode pad 33a and the second electrode pad 33b desirably contain gold and more desirably are substantially composed of only gold. For example, the first electrode pad 33a and the second electrode pad 33b can each have a two-layer structure consisting of a base layer that improves adhesion with the base 31 and a surface layer that contains gold and suppresses oxidation.

In addition, the base member 30 includes a first outer electrode 35a, a second outer electrode 35b, a third outer electrode 35c, and a fourth outer electrode 35d. The first to fourth outer electrodes 35a to 35d are provided on the lower surface 31B of the base 31. The first outer electrode 35a and the second outer electrode 35b are terminals for electrically connecting an external substrate, which is not illustrated, and the crystal vibrator 1 to each other. The third outer electrode 35c and the fourth outer electrode 35d are dummy electrodes to or from which no electrical signals or the like are input or output, but, in an alternative aspect, the third outer electrode 35c and the fourth outer electrode 35d may instead be ground electrodes that ground the cover member 40 and thereby improve an electromagnetic shielding function of the cover member 40. Note that the third outer electrode 35c and the fourth outer electrode 35d may instead be omitted.

The first electrode pad 33a and the second electrode pad 33b are disposed in a line along the Z′ axis direction on an end portion of the base member 30 that is on the −X axis direction side. The first outer electrode 35a and the second outer electrode 35b are disposed in a line along the Z′ axis direction on an end portion of the base member 30 that is on the −X axis direction side. The third outer electrode 35c and the fourth outer electrode 35d are disposed in a line along the Z′ axis direction on an end portion of the base member 30 that is on the +X axis direction side. The first electrode pad 33a is electrically connected to the first outer electrode 35a via a first through electrode 34a that penetrates through the base 31 in the Y′ axis direction. The second electrode pad 33b is electrically connected to the second outer electrode 35b via a second through electrode 34b that penetrates through the base 31 in the Y′ axis direction.

In another exemplary aspect, the first electrode pad 33a and the second electrode pad 33b can instead be respectively electrically connected to the first outer electrode 35a and the second outer electrode 35b via side surface electrodes provided on side surfaces of the base 31 connecting the upper surface 31A and the lower surface 31B to each other. The first to fourth outer electrodes 35a to 35d may instead be castellated electrodes that are provided in a recessed manner in the side surfaces of the base 31.

Yet further, the base member 30 includes a first electrically conductive holding member 36a and a second electrically conductive holding member 36b, which form a pair of electrically conductive holding members. The first electrically conductive holding member 36a and the second electrically conductive holding member 36b are used to mount the crystal vibration element 10 on the base member 30 and electrically connect the crystal vibration element 10 to the base member 30. The first electrically conductive holding member 36a electrically connects the first electrode pad 33a to the first connection electrode 16a. The second electrically conductive holding member 36b electrically connects the second electrode pad 33b to the second connection electrode 16b. The first electrically conductive holding member 36a and the second electrically conductive holding member 36b hold the crystal vibration element 10 at a certain distance from the base member 30 so that the excitation part 17 can be excited.

In the exemplary aspect, the first electrically conductive holding member 36a and the second electrically conductive holding member 36b include a cured electrically conductive adhesive such as a thermosetting resin or a light-curable resin, and the main component of the first electrically conductive holding member 36a and the second electrically conductive holding member 36b is, for example, silicone resin. The first electrically conductive holding member 36a and the second electrically conductive holding member 36b contain electrically conductive particles and, for example, metal particles containing silver (Ag) are used as the electrically conductive particles. The first electrically conductive holding member 36a bonds the first electrode pad 33a to the first connection electrode 16a and the second electrically conductive holding member 36b bonds the second electrode pad 33b to the second connection electrode 16b.

It is noted that the main component of the first electrically conductive holding member 36a and the second electrically conductive holding member 36b is not limited to silicone resin so long as the main component is a curable resin, and for example, the main component may be epoxy resin or acrylic resin. In addition, the way in which electrical conductivity is imparted to the first electrically conductive holding member 36a and the second electrically conductive holding member 36b is not limited to the use of silver particles, and electrically conductivity may alternatively be imparted by using other metals, electrically conductive ceramics, electrically conductive organic materials, and so on. The main component of the first electrically conductive holding member 36a and the second electrically conductive holding member 36b may be an electrically conductive polymer.

Moreover, the resin composition of the first electrically conductive holding member 36a and the second electrically conductive holding member 36b may contain appropriately chosen additives. The additives may be, for example, adhesion-imparting agents, fillers, thickeners, sensitizers, anti-aging agents, defoamers, and so on for improving the workability and preservability of the electrically conductive adhesives. In addition, a filler may be added for the purpose of increasing the strength of the cured material or for helping to maintain the distance between the base member 30 and the crystal vibration element 10.

Next, the cover member 40 (or cover) will be described.

The cover member 40 is bonded to the base member 30 and forms an internal space 49 in which the crystal vibration element 10 is accommodated between the cover member 40 and the base member 30. The internal space 49 is, for example, sealed in a vacuum state, but may instead be sealed in a state where the internal space 49 is filled with an inert gas, such as nitrogen or a noble gas, for example. In the exemplary aspect, the cover member 40 is formed of a material that has higher toughness than the base 31. From the viewpoint of suppressing damage due to impacts, the material of the cover member 40 is preferably a tough material that has greater resistance to brittle fracturing than the base 31. From the viewpoint of absorbing impacts, the material of the cover member 40 preferably is an elastic material or a plastic material that deforms more easily than the base 31. Furthermore, the material of the cover member 40 is desirably an electrically conductive material and even more desirably a metal having a high degree of air tightness. Moreover, the cover member 40 is constructed to provide an electromagnetic shielding function for reducing the entry and exit of electromagnetic waves into and out of the internal space 49 by forming the cover member 40 of an electrically conductive material. From the viewpoint of suppressing generation of thermal stress, the material of the cover member 40 is preferably a material having a coefficient of thermal expansion close to that of the base 31, and, for example, is an Fe—Ni—Co-based alloy whose coefficient of thermal expansion around room temperature matches that of glass or ceramic over a wide range of temperatures.

As further shown, the cover member 40 has a planar top surface part 41 and a side wall part 42 that is connected to the outer periphery of the top surface part 41 and extends in a direction that intersects the main surfaces of the top surface part 41. As shown in FIG. 2, the cover member 40 additionally includes a flange part 43 that is connected to the leading end of the side wall part 42 located on the side near the base member 30 and that extends outwardly when the upper surface 31A of the base 31 is seen in plan view. In other words, the top surface part 41 is connected to one end of the side wall part 42, the flange part 43 is connected to the other end of the side wall part 42, and the top surface part 41 and the flange part 43 extend in opposite directions from the side wall part 42. The top surface part 41 faces the base member 30 with the crystal vibration element 10 interposed therebetween and the side wall part 42 surrounds the periphery of the crystal vibration element 10 in directions parallel to the XZ′ plane. The flange part 43 extends in a frame-like shape at a position nearer to the base member 30 than the crystal vibration element 10 is. The flange part 43 increases the area of contact between the cover member 40 and the bonding member 50 and improves the strength of the bond between the base member 30 and the cover member 40.

The planar shape of the cover member 40 in plan view in a direction perpendicular to the main surfaces thereof is, for example, a rectangular shape. However, it is noted that the planar shape of the cover member 40 is not limited to this shape, and may instead be a polygonal shape, a circular shape, an elliptical shape, or a combination of these shapes in alternative aspects.

Next, the bonding member 50 will be described.

The bonding member 50 is provided along the entire outer peripheries of the base member 30 and the cover member 40 and has a rectangular frame-like shape. When the upper surface 31A of the base member 30 is seen in plan view, the first electrode pad 33a and the second electrode pad 33b are disposed inside from the bonding member 50 and the bonding member 50 is provided so as to surround the crystal vibration element 10. The bonding member 50 bonds the base member 30 to the cover member 40 and seals the internal space 49. Specifically, the bonding member 50 bonds the base 31 to the flange part 43. From the viewpoint of suppressing fluctuations in the frequency characteristics of the crystal vibration element 10, the material of the bonding member 50 desirably has low moisture permeability, and even more desirably has low gas permeability. From these viewpoints, the material of the bonding member 50 is desirably a metal. As an example, the bonding member 50 is formed of a metallization layer composed of molybdenum (Mo) provided on the upper surface 31A of the base 31 and a metallic solder layer composed of a gold-tin (Au—Sn) eutectic alloy provided between the metallization layer and the flange part 43.

In an alternative aspect, the bonding member 50 can instead be formed of an inorganic adhesive, such as a silicon-based adhesive containing water glass or the like, or a calcium-based adhesive containing cement or the like. The material of the bonding member 50 may be formed of an organic adhesive such as an epoxy-based, a vinyl-based, an acrylic-based, a urethane-based or a silicone-based adhesive. In the case where the bonding member 50 is formed of an inorganic or organic adhesive, a coating having a lower gas permeability than the adhesive may be provided on the outside of the bonding member 50 in order to reduce gas permeability. The base member 30 and the cover member 40 may be bonded to each other using seam welding.

Next, the configuration of an outer edge part of the crystal vibrator 1 and the vicinity thereof when the upper surface 31A of the base 31 is seen in plan view will be described.

The cover member 40 has an outer edge part 47 and the base member 30 has an outer edge part 37. The outer edge part 47 of the cover member 40 is an end portion that is on the opposite side from the side of the flange part 43 that is connected to the side wall part 42. Moreover, the outer edge part 37 of the base member 30 is an end portion of the base 31 that is located furthest toward the outside in a direction parallel to the XZ′ plane. In other words, the outer edge part 37 of the base member 30 is the outer edge part 37 of the base 31. An outer edge part of the crystal vibrator 1 is formed of the outer edge part 47 of the cover member 40 and the outer edge part 37 of the base member 30. In other words, part of the outer edge part 47 of the cover member 40 is located outside the base 31.

As shown in FIG. 3, for example, when the upper surface 31A of the base 31 is seen in plan view, the base 31 has an outside-of-frame region 39 that is located outside the bonding member 50, the outside-of-frame region 39 of the base 31 has a narrow part 39N where a width 39L between the outer edge part 37 of the base 31 and the bonding member 50 is smaller than the width in other parts, and the outer edge part 47 of the cover member 40 is located outside the narrow part 39N of the base 31. Furthermore, the outside-of-frame region 39 of the base 31 has a wide part 39W where the width 39L between the outer edge part 37 of the base 31 and the bonding member 50 is larger than that in the narrow part 39N, and the outer edge part 47 of the cover member 40 is located inside the wide part 39W of the base 31. In other words, when the width 39L of the outside-of-frame region 39 is small, the outer edge part 47 of the cover member 40 protrudes outwardly from the outer edge part 37 of the base 31, and when the width 39L of the outside-of-frame region 39 is large, the outer edge part 37 of the base 31 protrudes outwardly from the outer edge part 47 of the cover member 40. The outer edge part 37 of the base 31 forms the outer edge part of the crystal vibrator 1 at the wide part 39W and the outer edge part 47 of the cover member 40 forms the outer edge part of the crystal vibrator 1 at the narrow part 39N.

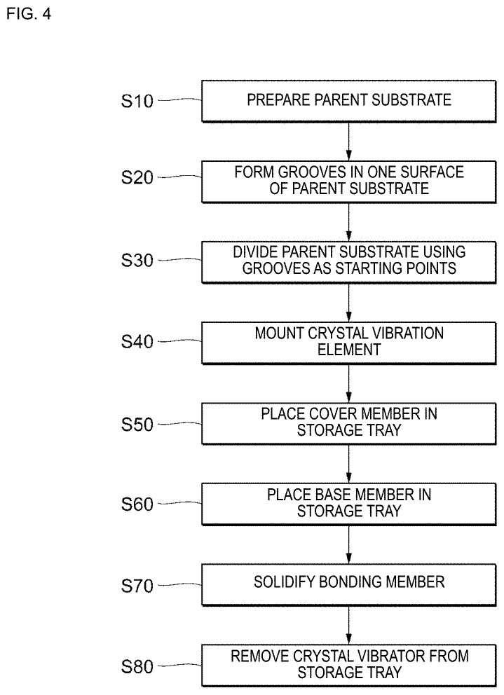

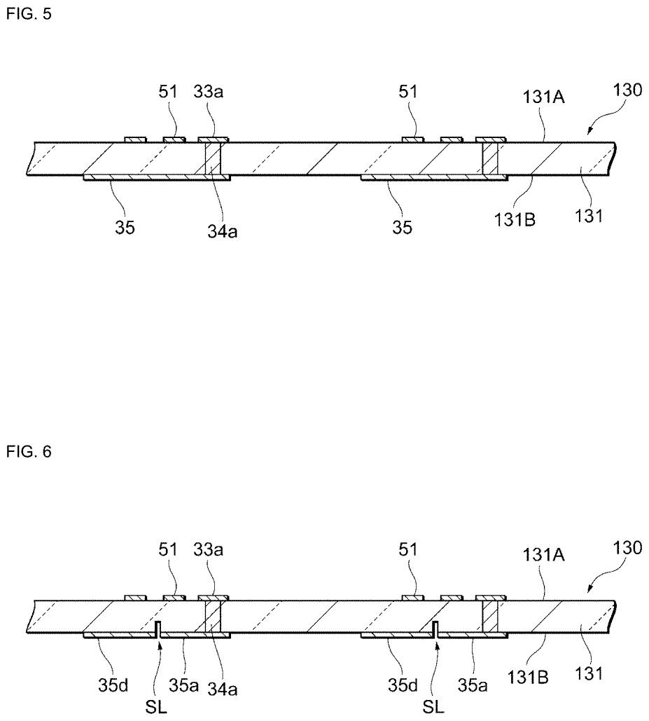

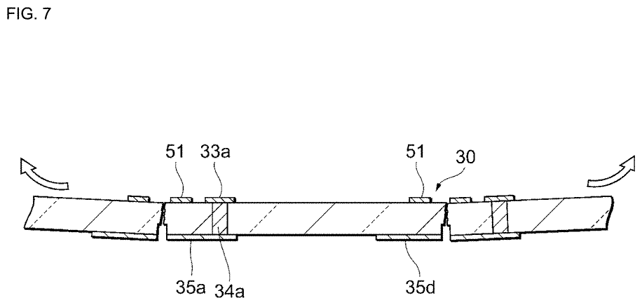

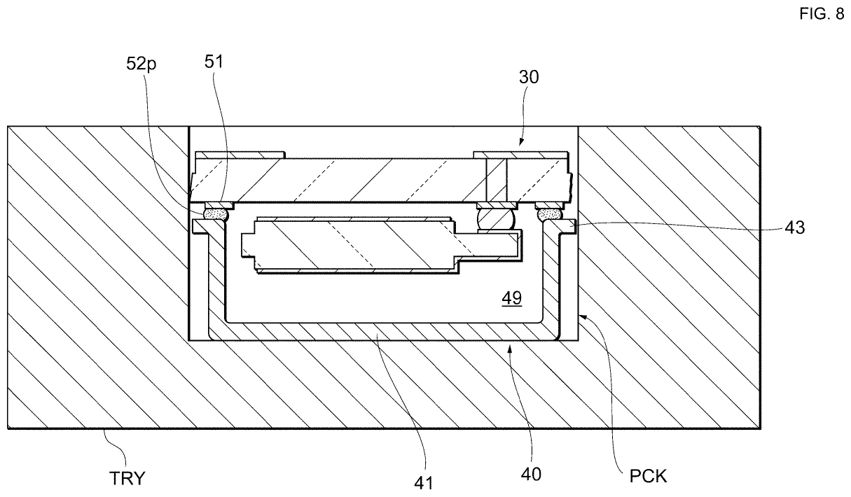

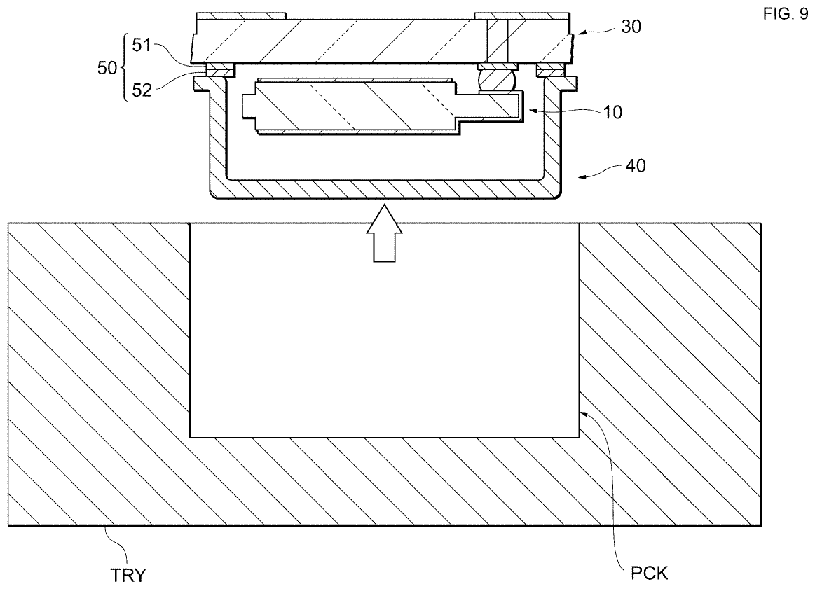

Next, a method of manufacturing the crystal vibrator 1 will be described while referring to FIGS. 4 to 9. FIG. 4 is a flowchart schematically illustrating a method of manufacturing the crystal vibrator according to the first exemplary embodiment. FIG. 5 is a sectional view schematically illustrating a step of preparing a parent substrate. FIG. 6 is a sectional view schematically illustrating a step of forming grooves in the parent substrate. FIG. 7 is a sectional view schematically illustrating a step of dividing the parent substrate. FIG. 8 is a sectional view schematically illustrating a step of bonding a base member and a cover member to each other. FIG. 9 is a sectional view schematically illustrating a step of removing a crystal vibrator.

First, a parent substrate is prepared (S10).

As illustrated in FIG. 5, an alumina parent substrate 130 includes a parent base 131 composed of alumina, for example. The parent base 131 is formed by sintering an alumina green sheet. The electrode pad 33a and a metallization layer 51 of the bonding member 50 are formed on an upper surface 131A of the parent base 131, a metal layer 35 is formed on a lower surface 131B of the parent base 131, and a through electrode 34a is formed inside the parent base 131 so as to connect the electrode pad 33a and the metal layer 35 to each other. At least part of each of the electrode pad 33a, the metallization layer 51, the metal layer 35, and the through electrode 34a is formed by sintering, together with the alumina green sheet, the respective precursors thereof, which are provided by being applied to the surface and filled into the through hole of the alumina green sheet. The parent base 131 may be formed of a wafer cut from an ingot. At least part of each of the electrode pad 33a, the metallization layer 51, and the metal layer 35 may be formed by performing plating or printing after sintering the parent base 131. In the cross section illustrated in FIG. 5, the metallization layer 51 has a rectangular shape, but it is noted that the metallization layer 51 is not limited to having a rectangular shape. The cross-sectional shape of the metallization layer 51 may be a convex shape, a trapezoidal shape, a semicircular shape, a semi-elliptical shape, or the like, in alternative aspects. In addition, at least part of each of the electrode pad 33a, the metallization layer 51, and the metal layer 35 may be formed using any of a variety of vapor phase growth methods such as physical vapor deposition (PVD) and chemical vapor deposition (CVD).

Next, grooves are formed in one surface of the parent substrate (S20).

Grooves SL are formed in the lower surface 131B of the parent base 131 using a scribing wheel, for example. This Step S20 is a scribing step in which scribing and breaking are performed in order to divide the parent substrate 130 into individual pieces, and the grooves SL function as scribing lines. As illustrated in FIG. 6, when the lower surface 131B of the parent base 131 is seen in plan view, the grooves SL are formed in regions located between adjacent metallization layers 51 and overlapping the metal layers 35 and extend along the metallization layers 51. The grooves SL are formed by cutting through the metal layers 35 and removing part of the parent base 131. Each metal layer 35 divided by a groove SL forms the outer electrodes 35a and 35d. Since the parent base 131 has been made thinner in order to reduce the size and thickness of the crystal vibrator 1, breaking of the parent substrate 130 can be carried out when the grooves SL, which are scribe lines, are formed on only one side of the parent substrate 130. Therefore, the grooves SL were formed only in the lower surface 131B of the parent substrate 130 in order to reduce the number of steps and thereby reduce the manufacturing cost and shorten the manufacturing lead time. In this embodiment, the grooves SL are formed in the parent substrate 130 after the green sheet has been sintered, but the grooves SL may be formed before firing the green sheet, and a parent substrate 131 in which the grooves SL have been already formed may be obtained by performing firing in additional exemplary aspects.

Next, the parent substrate is divided into individual pieces using the grooves as starting points (S30).

In particular, the Step S20 is a breaking step in which scribing and breaking are performed in order to divide the parent substrate 130 into individual pieces. As illustrated in FIG. 7, the parent substrate 130 is bent so that tensile stress concentrates at the grooves SL. This causes cracks to grow starting from the grooves SL and the parent base 131 is split between adjacent metallization layers 51. The depth of the grooves SL is preferably equal to or more than 25% and equal to or less than 50% of the thickness of the parent base 131. If the depth of the grooves SL is smaller than 25% of the thickness of the parent base 131, defects may occur in which part of the parent substrate 130 cannot be broken. On the other hand, if the depth of the grooves SL is greater than 50% of the thickness of the parent base 131, the processing time needed to form the grooves SL will increase and productivity will be degraded. In addition, in this case, there will be a risk of unintended cracking of the parent substrate 130 occurring when transporting the parent substrate 130.

Next, the crystal vibration element is mounted (S40).

First, an electrically conductive adhesive paste containing a thermosetting resin composition is prepared. Next, the base member 30 is placed on a hot plate that has not yet been heated up. Next, the electrically conductive adhesive paste is applied to the electrode pads 33a and 33b of the base member 30. Next, the crystal vibration element 10 is placed on the electrically conductive adhesive paste so that the leading ends thereof do not contacts the base member 30. Next, the electrically conductive adhesive paste is cured by being heated using the hot plate.

Preheating for adjusting the viscosity of the electrically conductive adhesive paste may be performed prior to placing the crystal vibration element 10 on the electrically conductive adhesive paste. Furthermore, the resin composition of the electrically conductive adhesive paste is not limited to a thermosetting resin composition and may instead be a light (UV) curable resin composition. In this case, Step S40 may include a step of irradiating the electrically conductive adhesive paste with light (UV).

Next, the base member and the cover member are bonded to each other.

First, the cover member is placed in a storage tray (S50). Next, the base member is placed in the storage tray (S60). Next, the bonding member is solidified (S70). As illustrated in FIG. 8, a storage tray TRY has an opening PCK in which the cover member 40 can be placed with almost no gap therebetween. In Step S50, the cover member 40 is placed in the opening PCK with the top surface part 41 facing the bottom of the opening PCK. Next, metal solder 52p is provided on the flange part 43. The metal solder 52p is a gold-tin (Au—Sn) eutectic alloy. The metal solder 52p may be provided on the metallization layer 51. Next, the base member 30 is placed in the opening PCK with the crystal vibration element 10 facing downward. In the cross section illustrated in FIG. 8, the dimensions of the opening PCK are slightly larger than the dimensions of the base member 30. In other words, the dimensions of the base member 30 are slightly smaller than the dimensions of the cover member 40. Therefore, in the opening PCK, misalignment of the base member 30 is larger than misalignment of the cover member 40. For example, in a direction parallel to the cross section illustrated in FIG. 8, the outer edge part 47 of the cover member 40 is positioned so as to overlap part of a region outside the base 31 or part of the outer edge part 37 of the base 31. Next, the metal solder 52p is softened by being heated, and the softened metal solder 52p is then solidified by being cooled. The solidified metal solder 52p forms a metal solder layer 52 and seals the internal space 49. In this embodiment, the metal solder 52p is provided on the flange part 43 after the cover member 40 has been placed in the opening PCK, but the metal solder 52p may instead be provided on the flange part 43 in advance.

Finally, the crystal vibrator is removed from the storage tray (S80).

It is noted that the step of bonding the base member 30 and the cover member 40 is merely an example. The base member 30 and the cover member 40 may be bonded to each other using another method in alternative aspects. For example, the distance between the metallization layer 51 and the outer edge part 37 of the base 31 may be measured and the base member 30 and the cover member 40 may be bonded to each other after adjusting the positional relationship therebetween so that the outer edge part 47 of the cover member 40 is located outside the base 31 in a region where this distance is small.

As described above, in the first exemplary embodiment, the toughness of the cover member 40 is greater than the toughness of the base 31, and at least part of the outer edge part 47 of the cover member 40 is located outside the base 31 when the upper surface 31A of the base 31 is seen in plan view. As a result, the probability of the bases 31 contacting each other when the crystal vibrators 1 contact each other is reduced, and the probability of the cover members 40 contacting each other or the bases 31 and the cover members 40 contacting each other is increased. The bases 31, which have a lower toughness, are more likely to be damaged by external impacts, whereas the cover members 40, which have a higher toughness, are less likely to be damaged by external impacts than the bases 31. Therefore, damage to the bases 31 caused by contact between the crystal vibrators 1 during manufacturing steps such as a cleaning step can be suppressed, and a decrease in the yield of the crystal vibrators 1 can be reduced. In particular, when the base 31 is made thinner and the outside-of-frame region 39 is made narrower on the whole in order to reduce the size and thickness of the crystal vibrator 1, the likelihood that damage occurring from the outer edge part 37 of the base 31 will affect the internal space 49 is increased. However, according to this embodiment, since damage to the base 31 is suppressed, the crystal vibrators 1 can be reduced in size and thickness while suppressing a reduction in yield.

The base 31 has the outside-of-frame region 39 located outside the bonding member 50 and the outer edge part 47 of the cover member 40 is located outside the narrow part 39N of the outside-of-frame region 39. This configuration enables a decrease in yield to be suppressed by especially protecting the narrow part 39N from external impacts, the narrow part 39N being more prone to performance degradation in which damage generated from the outer edge part 37 of the base 31 reaches the internal space 49.

The material of the base 31 is a ceramic in an exemplary aspect.

As a result, even when the base 31 is formed of a ceramic, which is a brittle material that is easily cracked or otherwise damaged by external impacts, according to this embodiment, a decrease in the yield of the crystal vibrators 1 can be suppressed.

Moreover, the material of the cover member 40 is a metal in an exemplary aspect.

As a result, the cover members 40 is constructed to deform and absorb an impact when the crystal vibrators 1 collide with each other. Therefore, external impacts to the bases 31 are reduced when the cover members 40 touch the bases 31.

The material of the bonding member 50 is a metal in an exemplary aspect.

As a result, vacuum sealing is realized by metal bonding, and according to this embodiment, the incidence of vacuum failures resulting from damage to the base 31 is reduced.

In this embodiment, the crystal vibration element 10 is used as a vibration element.

As a result, according to this embodiment, a reduction in yield is suppressed by reducing damage to the bases 31 even for crystal vibrators that are sensitive to the atmosphere of the vibration elements and whose frequencies are liable to fluctuate.

Hereafter, the configuration of a crystal vibrator 1 according to another embodiment of the present invention will be described. In the following embodiment, description of matters common to the first exemplary embodiment described above is omitted and only the differences are described. In particular, the same operational effects resulting from the same configurations are not repeatedly described.

### Second Exemplary Embodiment

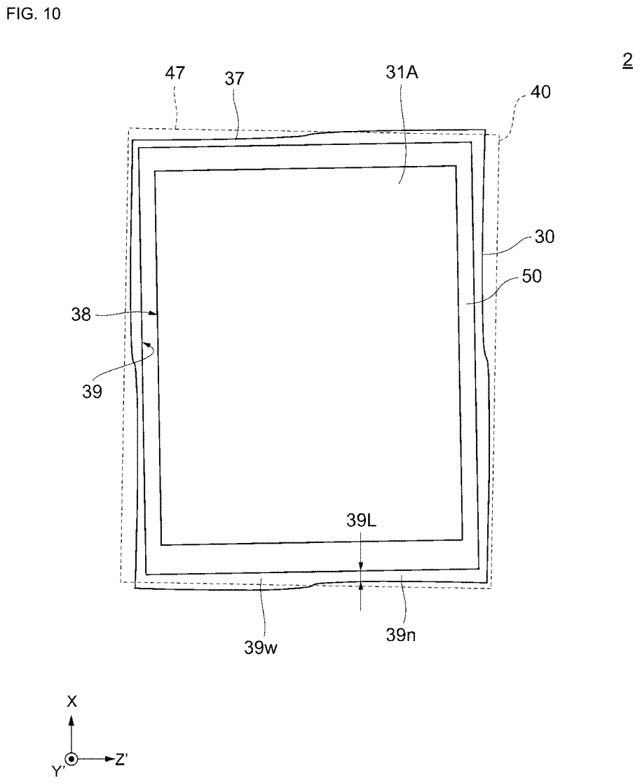

Next, the configurations of an outer edge part and the vicinity thereof in a crystal vibrator 2 according to a second exemplary embodiment will be described while referring to FIG. 10. FIG. 10 is a plan view schematically illustrating the positional relationship between a base member, a bonding member, and a cover member in the second embodiment.

As shown, the outer edge part 47 of the cover member 40 is located outside the base 31 on two opposing sides of the cover member 40. Specifically, when the upper surface 31A of the base 31 is seen in plan view, the outer edge part 47 of the cover member 40 has a rectangular shape having a pair of long sides and a pair of short sides, the entirety of each of the pair of long sides is located outside the base 31. According to this configuration, when the crystal vibrators 1 are aligned in the same direction in order to, for example, screen the crystal vibrators 1 with respect to their characteristics or appearance, the bases 31 do not contact each other at either of the opposing long sides, and therefore a decrease in the yield of the crystal vibrators 1 caused by damage to the bases 31 is suppressed.

### Third Exemplary Embodiment

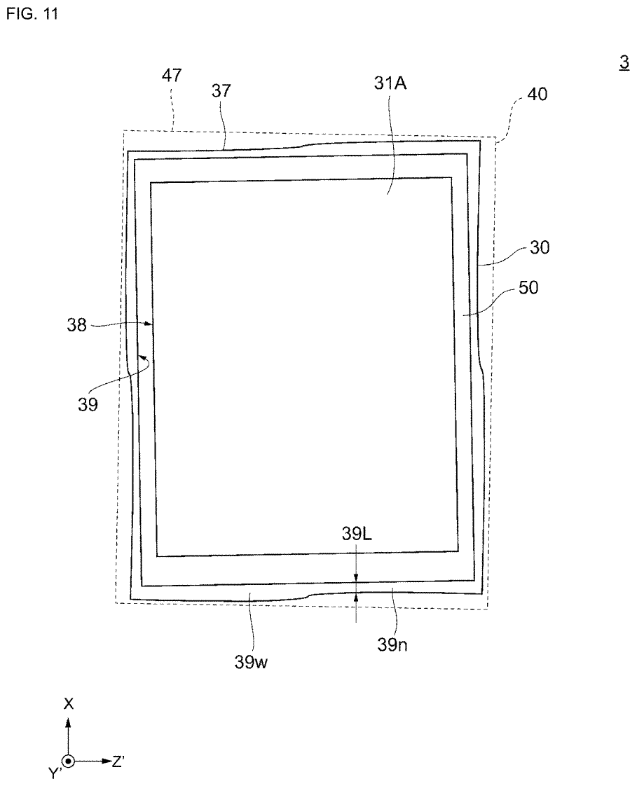

Next, the configurations of an outer edge part and the vicinity thereof in a crystal vibrator 3 according to a third exemplary embodiment will be described while referring to FIG. 11. FIG. 11 is a plan view schematically illustrating the positional relationship between a base member, a bonding member, and a cover member in the third embodiment.

The outer edge part 47 of the cover member 40 is located outside the base 31 along the entire periphery thereof. Specifically, the pair of long sides and the pair of short sides of the outer edge part 47 are entirely located outside the base 31. In other words, the entire base 31 is covered by the cover member 40.

According to this configuration, the incidence of damage to the bases 31 is further reduced and a reduction in the yield of the crystal vibrators 1 is suppressed.

### Fourth Exemplary Embodiment

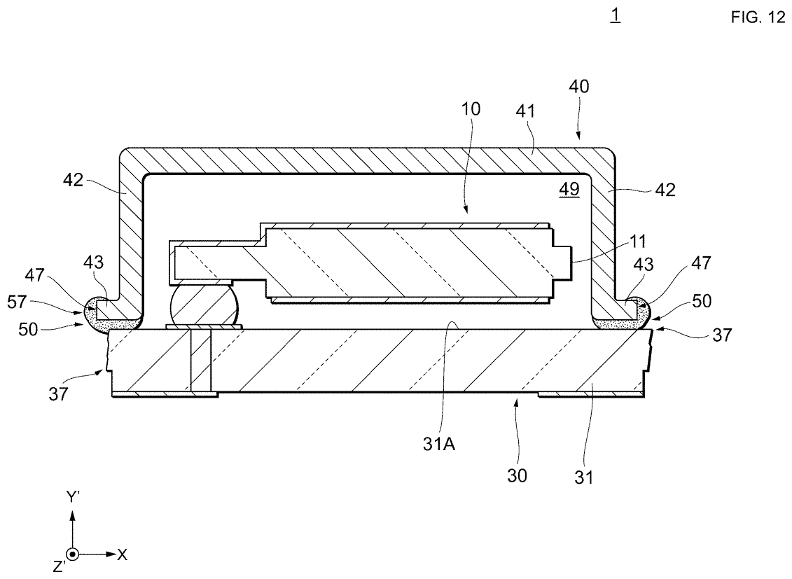

Next, the configurations of an outer edge part and the vicinity thereof in a crystal vibrator 4 according to a fourth exemplary embodiment will be described while referring to FIG. 12. FIG. 12 is a sectional view schematically illustrating the configuration of the crystal vibrator according to the fourth embodiment.

As shown, the outer edge part 47 of the cover member 40 is covered by the bonding member 50. Moreover, the toughness of the bonding member 50 is higher than the toughness of the cover member 40. In other words, when the upper surface 31A of the base 31 is seen in plan view, an outer edge part 57 of the bonding member 50 is located outside the outer edge part 47 of the cover member 40. Therefore, the outer edge part 57 of the bonding member 50 is located outside the base 31 in at least the part where the outer edge part 47 of the cover member 40 is located outside the base 31. In an exemplary aspect, the entirety of the outer edge part 57 of the bonding member 50 is preferably located outside the base 31. In other words, the outer edge part 57 of the bonding member 50 is also desirably located outside the base 31 in parts where the outer edge part 47 of the cover member 40 is located inside the base 31.

As a result, damage to the bases 31 caused by the crystal vibrators 1 touching each other is more effectively suppressed, and therefore a reduction in the yield of the crystal vibrators 1 is further suppressed. It is noted that the member covering the outer edge part 47 of the cover member 40 is not limited to the bonding member 50 so long as the member is tougher than the cover member 40. For example, the outer edge part 47 of the cover member 40 may be covered by a coating provided outside the bonding member 50. The member covering the outer edge part 47 of the cover member 40 is, for example, desirably composed of an elastic material or a plastic material that deforms more easily than the cover member 40.

Hereafter, some or all exemplary embodiments of the present invention are listed and their effects are described. However, it is noted that the present invention is not limited to the following exemplary embodiments.

According to an exemplary aspect of the present invention, a crystal vibrator is provided that includes a base having a main surface, a piezoelectric vibration element mounted on the main surface of the base, a cover member that has a recess in which the piezoelectric vibration element is accommodated and that is tougher than the base, and a bonding member that is provided in a frame-like shape so as to surround the piezoelectric vibration element when the main surface of the base is seen in plan view and that bonds the base and the cover member to each other. When the main surface of the base is seen in plan view, at least part of an outer edge part of the cover member is located outside the base.

As a result, when the crystal vibrators contact each other, the probability of the bases contacting each other is reduced, and the probability of the cover members contacting each other or the bases and the cover members contacting each other is increased. Moreover, the bases, which have a lower toughness, are more likely to be damaged by external impacts, whereas the cover members, which have a higher toughness, are less likely to be damaged by external impacts than the bases. Therefore, damage to the bases caused by contact between the crystal vibrators during manufacturing steps, such as a cleaning step, can be suppressed, and a decrease in the yield of the crystal vibrators can be suppressed. In particular, when the base is made thinner and an outside-of-frame region is made narrower on the whole in order to reduce the size and thickness of the crystal vibrator, the likelihood that damage occurring from the outer edge part of the base will affect the internal space is increased. However, according to this embodiment, since damage to the base can be suppressed, the crystal vibrators can be reduced in size and thickness while suppressing a reduction in yield.

As an exemplary aspect, when the main surface of the base is seen in plan view, the base has an outside-of-frame region that is located outside the bonding member, the outside-of-frame region of the base has a narrow part where a width between the outer edge part of the base and the bonding member is smaller than the width in other parts, and the outer edge part of the cover member is located outside the narrow part of the base.

This configuration enables a decrease in yield to be suppressed by especially protecting the narrow part from external impacts, the narrow part being more prone to performance degradation in which damage generated from the outer edge part of the base reaches the internal space.

As an exemplary aspect, when the main surface of the base is seen in plan view, the cover member has a rectangular shape and the outer edge part of the cover member is located outside the base on two opposing sides of the cover member.

According to this configuration, when the crystal vibrators are aligned in the same direction in order to, for example, screen the crystal vibrators with respect to their characteristics or appearance, contact between the bases can be suppressed at all of the opposing sides and therefore a decrease in the yield of the crystal vibrators caused by damage to the bases can be suppressed.

As an exemplary aspect, the outer edge part of the cover member is covered by a member having higher toughness than the cover member.

As a result, damage to the bases caused by the crystal vibrators touching each other can be more effectively suppressed, and therefore a reduction in the yield of the crystal vibrators can be further suppressed.

As an exemplary aspect, a material of the base is a ceramic.

With this configuration, even when the base is formed of a ceramic, which is a brittle material that is easily cracked or otherwise damaged by external impacts, according to this embodiment, a decrease in the yield of the crystal vibrators can be suppressed.

As an exemplary aspect, a material of the cover member is a metal.

With this configuration, the cover members are constructed to deform and absorb an impact when the crystal vibrators collide with each other. Therefore, external impacts to the bases is reduced when the cover members touch the bases.

As an exemplary aspect, a material of the bonding member is a metal.

As a result, vacuum sealing is realized by metal bonding, and according to this embodiment, the incidence of vacuum failures resulting from damage to the base is reduced.

As an aspect, the piezoelectric vibration element is a crystal vibration element.

As a result, according to this embodiment, a reduction in yield is suppressed by reducing damage to the bases even for crystal vibrators that are sensitive to the atmosphere of the vibration elements and whose frequencies are liable to fluctuate.

Embodiments of the present invention are not limited to crystal vibrators and may also be applied to piezoelectric vibrators. An example of a piezoelectric vibrator (e.g., piezoelectric resonator unit) is a crystal vibrator (e.g., quartz crystal resonator unit) including a crystal vibration element (e.g., quartz crystal resonator). The crystal vibration element employs a crystal piece (e.g., quartz crystal element) as a piezoelectric piece that is excited using the piezoelectric effect, but the piezoelectric piece may instead be formed of an appropriately chosen piezoelectric material such as a piezoelectric single crystal, a piezoelectric ceramic, a piezoelectric thin film, or a piezoelectric polymer film. For example, lithium niobate (LiNBO₃) can be given as an example of a piezoelectric single crystal. Similarly, examples of a piezoelectric ceramic include barium titanate (BaTiO₃), lead titanate (PbTiO₃), lead zirconate titanate (Pb(ZrₓTi₁₋ₓ)O₃; PZT), aluminum nitride (AlN), lithium niobate (LiNbO₃), lithium meta-niobate (LiNb₂O₆), bismuth titanate (Bi₄Ti₃O₁₂), lithium tantalate (LiTaO₃), lithium tetraborate (Li₂B₄O₇), langasite (La₃Ga₅SiO₁₄), and tantalum pentoxide (Ta₂O₅). The piezoelectric thin film may be formed by depositing the piezoelectric ceramic on a substrate composed of quartz, sapphire, or the like using a sputtering method, for example. Examples of the piezoelectric polymer film include polylactic acid (PLA), polyvinylidene fluoride (PVDF), and a vinylidene fluoride/trifluoroethylene (VDF/TrFE) copolymer. It is also noted that the various piezoelectric materials given above may be used by being stacked in layers or may be stacked on another member.

Embodiments of the present invention are not particularly limited so long as the embodiments include an element that require airtight or watertight sealing, and can be appropriately applied to various electronic elements, optical elements, mechanical elements, and so on.

As described above, according to an exemplary aspect of the present invention, a piezoelectric vibrator is provided that enables a reduction in yield to be suppressed.

In general, the exemplary embodiments are described above to enable easy understanding of the present invention and the embodiments are not to be interpreted as limiting the present invention. The present invention can be modified or improved without departing from the gist of the invention and equivalents to the present invention are also included in the scope of the present invention. In other words, appropriate design changes made to the embodiments by one skilled in the art are included in the scope of the present invention so long as the changes have the characteristics of the present invention. For example, the elements included in the embodiments and the arrangements, materials, conditions, shapes, sizes and so forth of the elements are not limited to those exemplified in the embodiments and can be changed as appropriate. For example, a vibration element and a vibrator of the present invention can be used in timing devices or load sensors. In addition, the elements included in the embodiments can be combined as much as technically possible and such combined elements are also included in the scope of the present invention so long as the combined elements have the characteristics of the present invention.

### REFERENCE SIGNS LIST

1 . . . crystal vibrator,
10 . . . crystal vibration element,
11 . . . crystal piece,
30 . . . base member,
31 . . . base,
37 . . . outer edge part of base member (base),
40 . . . cover member,
47 . . . outer edge part of cover member,
50 . . . bonding member

1. A piezoelectric vibrator comprising:
a base having a main surface;
a piezoelectric vibration element disposed on the main surface of the base;
a cover that has a recess to accommodate the piezoelectric vibration element and comprises a material that is tougher than a material of the base; and
a bonding member having a frame-like shape that surrounds the piezoelectric vibration element in a plan view of the main surface of the base, with the bonding member configured to bond the base to the cover,
wherein, in the plan view of the main surface of the base, at least part of an outer edge of the cover is located outside the base.

2. The piezoelectric vibrator according to claim 1,
wherein, in the plan view of the main surface of the base, the base has an outside-of-frame region that is located outside the bonding member.

3. The piezoelectric vibrator according to claim 2,
wherein the outside-of-frame region of the base has a narrow part where a width between an outer edge of the base and the bonding member is smaller than the width in other parts of outside-of-frame region of the base, and the outer edge of the cover is located outside the narrow part of the base.

4. The piezoelectric vibrator according to claim 1,
wherein, in the plan view of the main surface of the base, the cover has a rectangular shape, and the outer edge of the cover is located outside the base on two opposing sides of the cover.

5. The piezoelectric vibrator according to claim 1,
wherein the outer edge of the cover is covered by a member formed of a material having a higher toughness than the material of the cover.

6. The piezoelectric vibrator according to claim 1,
wherein the material of the base is a ceramic.

7. The piezoelectric vibrator according to claim 1,
wherein the material of the cover is a metal.

8. The piezoelectric vibrator according to claim 1,
wherein a material of the bonding member is a metal.

9. The piezoelectric vibrator according to claim 1,
wherein the piezoelectric vibration element is a crystal vibration element.

10. The piezoelectric vibrator according to claim 9,
wherein the crystal vibration element is configured to vibrate in a thickness shear vibration mode as a main vibration mode.

11. The piezoelectric vibrator according to claim 1,
wherein the material of the cover is tougher than the material of the base by having a greater resistance to brittle fracturing than the base.

12. The piezoelectric vibrator according to claim 1,
wherein the material of the cover is tougher than the material of the base by being an elastic material or a plastic material that is configured to more easily deform than the base.

13. A piezoelectric vibrator comprising:
a base;
a piezoelectric vibration element disposed on the base;
a cover having a recess that accommodates the piezoelectric vibration element; and
a bonding member surrounding the piezoelectric vibration element in a plan view of a main surface of the base and coupling the base to the cover,
wherein the cover comprises a material having a greater toughness than a material of the base, and
wherein an outer edge of at least part of the cover extends outside the base in the plan view of the main surface of the base.

14. The piezoelectric vibrator according to claim 13,
wherein the base has an outside-of-frame region that extends outside the bonding member in the plan view of the main surface of the base.

15. The piezoelectric vibrator according to claim 14,
wherein the outside-of-frame region of the base has a narrow part where a width between an outer edge of the base and the bonding member is smaller than the width in other parts of outside-of-frame region of the base, and the outer edge of the cover extends outside the narrow part of the base.

16. The piezoelectric vibrator according to claim 13,
wherein, in the plan view of the main surface of the base, the cover has a rectangular shape, and the outer edge of the cover extends outside the base on two opposing sides of the cover.

17. The piezoelectric vibrator according to claim 13,
wherein the outer edge of the cover is covered by a member formed of a material having a higher toughness than the material of the cover.

18. The piezoelectric vibrator according to claim 13,
wherein the piezoelectric vibration element is a crystal vibration element that is configured to vibrate in a thickness shear vibration mode as a main vibration mode.

19. The piezoelectric vibrator according to claim 13,
wherein the material of the cover has a greater toughness than the material of the base by having a greater resistance to brittle fracturing than the base.

20. The piezoelectric vibrator according to claim 13,
wherein the material of the cover has a greater toughness than the material of the base by being an elastic material or a plastic material that is configured to more easily deform than the base.
